(19) United States
(12) Patent Application Publication
(10) Pub. No.: US 2026/0271177 A1
(43) Pub. Date: Sep. 10, 2026

(54) PRINTED CIRCUIT BOARDS WITH ARC REDUCTION VOIDS

(71) Applicant: Micron Technology, Inc., Boise, ID (US)

(72) Inventors: Brilendra Murti Panta, Boise, ID (US); Joao Elmiro da Rocha Chaves, Middleton, ID (US)

(21) Appl. No.: 19/459,964

(22) Filed: Jan. 26, 2026

Related U.S. Application Data
(60) Provisional application No. 63/767,825, filed on Mar. 6, 2025.

(51) Int. Cl. H05K 1/02; H05K 1/11

(52) U.S. Cl. CPC H05K 1/0218; H05K 1/115; H05K 2201/09063

(57) ABSTRACT

Printed circuit boards with arc reduction voids are disclosed herein. In one embodiment, a printed circuit board (PCB) includes a conductor layer comprising an interconnect, a ground plane layer, and a layer including a void positioned between the conductor layer and the ground plane such that (a) the layer is devoid of any conductive elements positioned between the interconnect and the ground plane layer, and (b) the interconnect is electrically isolated from the ground plane layer. The void can be formed or filled by a non-conductive material, such as prepreg or core material. The void may have a footprint corresponding to the interconnect's footprint or span an area larger than the interconnect. Additional dielectric material sections can be positioned between the conductor layer and the void layer, the void layer and the ground plane, or a combination thereof.

### CROSS-REFERENCE TO RELATED APPLICATIONS

The present application claims priority to U.S. Provisional Patent Application No. 63/767,825, filed March 6, 2025, the disclosure of which is incorporated herein by reference in its entirety.

### TECHNICAL FIELD

The present disclosure relates generally to printed circuit boards. For example, several embodiments of the present technology described in detail below relate to printed circuit boards that incorporate arc reduction voids between (e.g., input voltage, power) conductors and ground layers, which is expected to reduce risk of electrical arcing, decrease noise, and/or allow for use of larger power traces.

### BACKGROUND

Printed circuit boards (PCBs) are widely used in electronic devices to mechanically support and electrically connect electronic components. For example, memory modules, such as dual inline memory modules (DIMMs), commonly utilize PCBs to communicably and/or electrically couple memory chips to other electronic components, such as controllers, clock drivers, and/or other circuits configured for power management or signal conditioning. More specifically, the memory chips, controllers, clock drivers, and/or other electronic components can be mounted on the PCB and electrically coupled to one another using interconnects (e.g., traces, vias, etc.) formed on or in the PCB.

As electronic devices become more complex and miniaturized, a number of challenges relating to managing power distribution, signal integrity, and thermal management have emerged. For example, recent developments in memory module technology have led to increased power demands and higher operating voltages that come with new considerations for PCB designers. As a specific example, the proximity of high-voltage traces to ground planes can potentially lead to undesired electrical effects (e.g., electrical arcing, noise or crosstalk, etc.), impacting safety, performance, and/or reliability of the module.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments shown, but are provided for explanation and understanding.

FIG. 1 illustrates a partially schematic cross-sectional side view of a layer arrangement for a printed circuit board.

FIG. 2A illustrates a partially schematic top plan view of a first side of a registered dual inline memory module configured in accordance with various embodiments of the present technology.

FIG. 2B illustrates a partially schematic top plan view of a second side of the registered dual inline memory module of FIG. 2A.

FIG. 3 illustrates a partially schematic top plan view of a ground plane for the registered dual inline memory module of FIG. 2A.

FIG. 4 illustrates a partially schematic top plan view of a conductor layer for the registered dual inline memory module of FIG. 2A.

FIG. 5 illustrates a partially schematic cross-sectional side view of a layer arrangement for a printed circuit board configured in accordance with various embodiments of the present technology.

FIG. 6 illustrates a partially schematic cross-sectional view of another layer arrangement for a printed circuit board configured in accordance with various embodiments of the present technology.

### DETAILED DESCRIPTION

As described in greater detail below, the technology disclosed herein relates to improving the design of printed circuit boards (PCBs). By adding a void between conductor layers and ground layers, the design increases a space between and better insulates the conductor layers from the ground layers, which is expected to reduce the risk of electrical arcing, decrease noise, and/or allow for enhanced conductor characteristics (e.g., larger widths and/or thicknesses). This approach is also expected to help prevent damage to electrical components and improve overall performance of power-intensive circuits, such as memory modules.

In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc. For example, although primarily described below in the context of PCBs for DIMMs, the present technology is not so limited. Indeed, aspects of the present technology are applicable in other contexts, such as (i) PCBs for other electronic devices (e.g., system-in-packages (SiPs), high-bandwidth memory (HBM) modules, other memory systems, etc.) and/or (ii) interposers, substrates, interface dies, interface wafers, etc.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein may be combined in any suitable manner to provide further examples or embodiments of the present technology.

Spatially relative terms (e.g., “beneath,” “below,” “over,” “under,” “above,” “upper,” “top,” “bottom,” “left,” “right,” “center,” “middle,” and the like) may be used herein for ease of description to describe one element’s or feature’s relationship relative to one or more other elements or features as illustrated in the figures. It will be understood that the spatially relative terms are intended to encompass different orientations of a device or system in use or operation, in addition to the orientation depicted in the figures. For example, if a device or system illustrated in the figures is rotated, turned, or flipped about a horizontal axis, elements or features described as “below” or “beneath” or “under” one or more other elements or features may then be oriented “above” the one or more other elements or features. Thus, the exemplary terms “below” and “under” are non-limiting and can encompass both an orientation of above and below. The device or system may additionally, or alternatively, be otherwise oriented (e.g., rotated ninety degrees about a vertical axis, or at other orientations) than illustrated in the figures, and the spatially relative descriptors used herein are interpreted accordingly. In addition, it will also be understood that when an element is referred to as being “between” two other elements, it can be the only element between the two other elements, or one or more intervening elements may also be present.

### A. Overview

As electronic devices become more complex and miniaturized, a number of challenges relating to managing power distribution, signal integrity, and thermal management have emerged. For example, recent developments in memory module technology have led to increased power demands and higher operating voltages. As a specific example, many memory modules, such as registered dual inline memory modules (RDIMMs), incorporate power management integrated circuits (PMICs) to regulate voltage and improve power efficiency. With the introduction of PMICs on dynamic double data rate fifth generation (DDR5) memory modules, the input voltages to these modules have increased. The higher input voltages have created new challenges in printed circuit board (PCB) design, particularly regarding the potential for electrical arcing between conductor layers (e.g., conductor layers including input voltage conductors, such as Vin bulk input areas) and nearby ground plane layers that can occur when there is (a) insufficient insulation between the layers and (b) a significant voltage difference between the conductor layers and the ground plane layers.

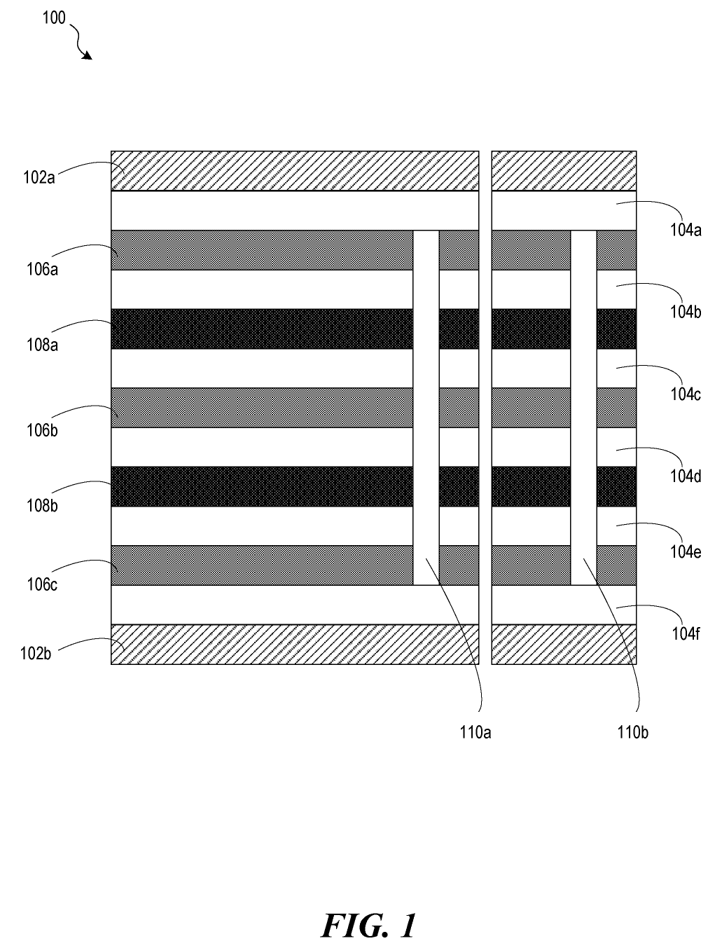

As a specific example, due to miniaturization and other design goals, PCBs for memory modules often utilize sections of dielectric material between adjacent layers of the PCB. The sections of dielectric material can serve as an insulative filler or spacer between the adjacent layers of the PCB. For example, FIG. 1 illustrates a cross-sectional side view of a layer arrangement 100 for a PCB. The layer arrangement 100 includes multiple layers 102, 106, and 108 stacked in a vertical configuration, representing a structure used in many memory modules. More specifically, the layer arrangement 100 includes a surface layer 102a and a surface layer 102b positioned at the top and bottom of the stack, respectively. Between these surface layers 102a and 102b, the layer arrangement 100 further includes a plurality of conductor layers 106 (individually identified in FIG. 1 as conductor layers 106a, 106b, and 106c), a plurality of ground plane layers 108 (individually identified in FIG. 1 as ground planes 108a and 108b), and vias 110a and 110b that extend vertically across multiple ones of the layers 106 and 108and that can be used to electrically couple two or more of the layers 102, 106, and/or 108to one another. Immediately adjacent ones of the layers 102, 106, and 108 in the layer arrangement 100 are separated from one another using sections of dielectric material 104 (individually identified in FIG. 1 as first through sixth sections of dielectric material 104a, 104b, 104c, 104d, 104e, and 104f). Each of the sections of dielectric material 104(a) serves as a filler or spacer between the immediately adjacent ones of the layers 102, 106, and 108 of the layer arrangement 100 and (b) is intended to provide electrical isolation between conductive elements of the immediately adjacent ones of the layers 102, 106, and 108. As shown, each of the sections of dielectric material 104 includes a height or thickness that is less than or equal to the immediately adjacent ones of the layers 102, 106, and 108, which can be an intentional characteristic implemented into the PCB design so as to minimize an overall height of the layer arrangement 100 (corresponding to the thickness of the PCB).

This approach, however, may not provide sufficient isolation between the conductor layers 106 and the adjacent ground planes 108 when dealing with higher voltages. For example, assuming the conductor layer 106b includes a Vin bulk area including an input voltage power trace or power via, higher input voltages on the power trace or via of the conductor layer 106b can (despite the presence of the sections of dielectric material 104c and 104d between the conductor layer 106b and the ground planes 108a and 108b, respectively) increase the likelihood of arc events between (a) the power trace or via and (b) the ground plane layers 108a and/or 108b due to higher voltage differences between (i) the power trace or via and (ii) the ground planes 108a and 108b. Such arc events can lead to over-compensation by a host power supply, potentially resulting in supply over-voltage or over-current conditions within the memory module. The consequences of these electrical issues in many memory module designs can be severe. For example, the PMIC and other components of the memory module can be placed at risk of damage and/or catching fire. Insufficient isolation between the layers 102, 106, and/or 108can also lead to electromagnetic interference (EMI) and crosstalk observed across electrical components of two or more of the layers 102, 106, and/or 108, which can increase noise and affect signal integrity. The above issues, stemming from increased operating voltages in incompatible PCB designs, can ultimately compromise overall performance and reliability of the corresponding memory modules.

To address these concerns, the present technology is directed generally to PCB designs that incorporate arc reduction voids between conductor layers (e.g., traces, vias, interconnects of the conductor layers) and ground planes. In some embodiments, the arc reduction voids can correspond to a layer in a PCB layer arrangement that is dedicated (e.g., solely) to electrical insulation. For example, the arc reduction void can be a layer in the PCB layer arrangement that is devoid of any conductive elements. As a specific example, an arc reduction void can be filled with and/or include non-conductive material positioned between a conductor layer (e.g., having power traces, vias, etc.) and one or more adjacent ground planes. The non-conductive material can be implemented in addition to sections of dielectric material that are typically interleaved with layers of a PCB, and may include or be formed of a same dielectric material. Such arc reduction voids are expected to reduce the risk of electrical arcing, decrease noise, and/or enable use of power traces with enhanced characteristics. More specifically, the voids can contribute an additional insulating barrier (or otherwise bolster electrical insulation) between a conductor layer and one or more adjacent ground planes, which is expected to significantly reduce the likelihood of unintended electrical discharge or arc events between the conductor layer and the adjacent ground plane(s). In addition, the void can increase separation between conductive elements of the conductor layer and the adjacent ground plane(s), which is expected to reduce noise coupling between the conductive elements and the ground plane(s), thereby (i) reducing electromagnetic interference and crosstalk and (ii) facilitating maintaining clean power delivery and signal integrity. Furthermore, the additional space and electrical insulation provided by the void is expected to facilitate use of wider and/or thicker power traces, which in turn is expected to reduce resistance and thereby enhance current-carrying capacity.

The present technology is therefore expected to effectively mitigate risks associated with higher input voltages that are or will in the future be used in many memory modules, such as DDR5 memory modules that implement PMICs. In particular, the improved isolation between conductor layers and ground layers is expected to (a) reduce the likelihood of over-compensation by a host power supply, and (b) reduce the occurrence of supply over-voltage and/or over-current conditions. In turn, the present technology is expected to (i) enhance the overall reliability and performance of the memory modules, and (ii) better protect critical components or electronics (e.g., PMICs) from potential damage or fire. The technology is therefore expected to provide a comprehensive solution to the challenges posed by increased voltage requirements in modern electronic devices (e.g., memory modules), facilitating safer and more efficient operation.

### B. Selected Embodiments of Printed Circuit Boards with Arc Reduction Voids, and Associated Systems, Devices, and Methods

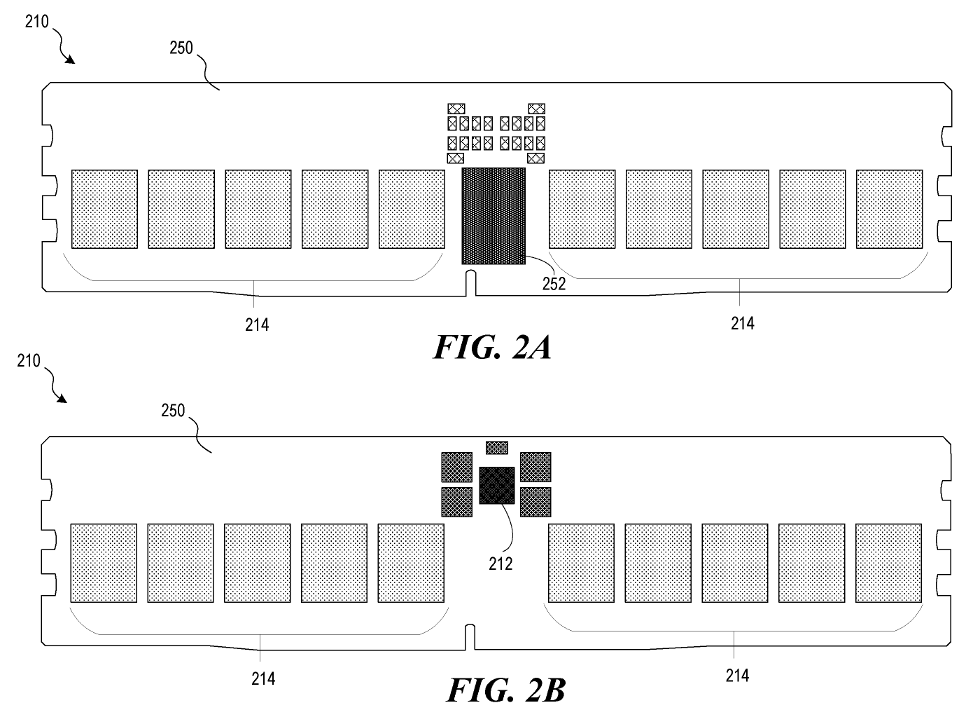

FIGS. 2A and 2B are partially schematic top plan views of a first side and a second side, respectively, of a memory module 210 configured in accordance with various embodiments of the present technology. In some embodiments, the memory module 210 can be a dual inline memory module (DIMM). As shown, the memory module 210 includes (i) a PCB 250 and (ii) a plurality of memory devices 214 mounted on the PCB 250 and distributed across the first and second sides of the memory module 210. In some embodiments, the memory devices 214 can include dynamic random-access memory (DRAM) devices.

As shown in FIG. 2A, the memory module 210 can include a registered clock driver 252 (RCD 252). In these embodiments, the memory module 210 can be a registered DIMM (RDIMM). As shown, the RCD 252 can be positioned in a central region of the first side of the memory module 210. In operation, the RCD 252 can be configured to manage clock and/or control signals for the memory devices 214, such as to facilitate communications between the memory devices 214 and a host device (not shown), such as a memory controller.

Referring now to FIG. 2B, the memory module 210 can further include a PMIC 212. In some embodiments, the PMIC 212 can be positioned in a central region of the second side of the memory module 210. The PMIC 212 can be configured to manage power distribution to various components of the memory module 210. For example, the PMIC 212 may regulate voltage levels for and control power efficiency of the memory devices 214.

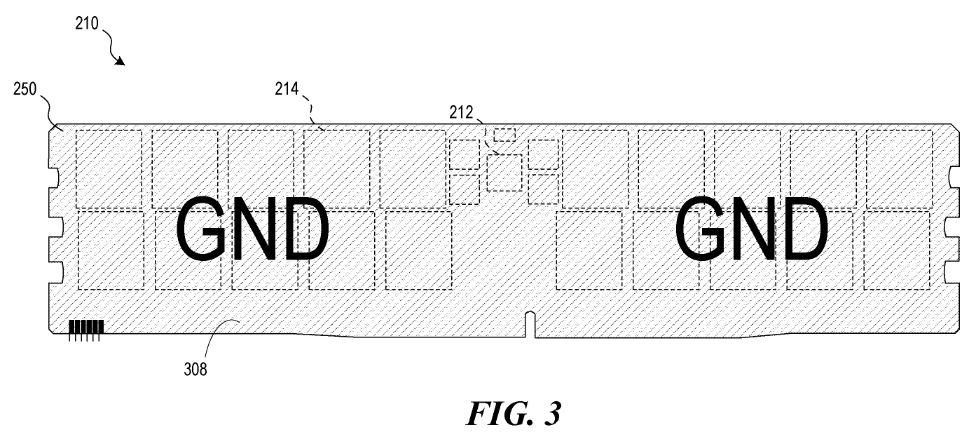

FIG. 3 illustrates a partially schematic top plan view of a ground plane layer 308 ("ground plane 308") of the PCB 250 of the memory module 210. The ground plane 308 may serve as a voltage reference plane for electrical signals within the memory module 210. The ground plane 308 may help to maintain a consistent ground potential across the memory module 210, which can be important for signal integrity and power distribution. In some cases, the configuration of the ground plane 308 may be designed to balance signal integrity, power distribution, and component placement within the memory module 210.

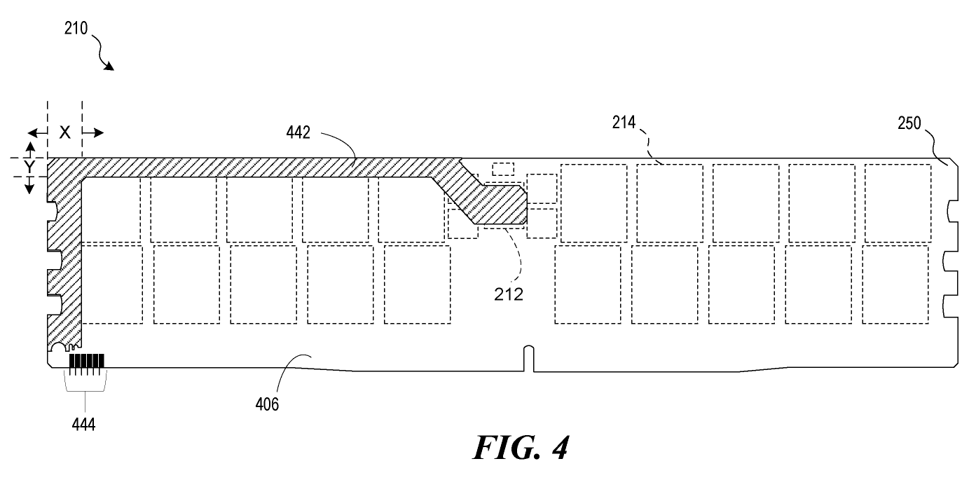

FIG. 4 illustrates a partially schematic top plan view of a conductor layer 406 of the PCB 250 of the memory module 210. As shown, the conductor layer 406 can include a power trace 442. In some embodiments, the power trace 442 can couple voltage input pins 444 (e.g., that are configured to receive voltage or power signals, such as on the order of 12 to 35 volts, from a coupled host power supply) to the PMIC 212. As a specific example, the power trace 442 can be a Vin_Bulk rail that provides an electrical connection pathway between the voltage input pins 444 and the PMIC 212. As such, the power trace 442 can extend between the voltage input pins 444 and a location corresponding to the PMIC 212.

As described in greater detail below, the PCB 250 of the memory module 210 can include a void between the conductor layer 406 and the ground plane 308 of FIG. 3. The void can be formed of or filled with an epoxy or another dielectric material and/or can be configured to (e.g., further) electrically insulate the conductor layer 406 from the ground plane 308 (thereby reducing the risk of arc events and/or noise coupling between the power trace 442 and the ground plane 308). The void can also be referred to herein as an "arc reduction void."

In some embodiments, use of the void can space the conductor layer 306 further away from the ground plane 308. In turn, the increased space and increased electrical insulation can enable use of a power trace with enhanced features or characteristics than is possible to safely use in other PCB designs. For example, the increased space and increased electrical insulation can permit the size of the power trace 442 to be increased in the X, Y, and/or Z directions (extending generally into and out of the drawings page), such as by using more copper in comparison to other PCB designs. As a specific example, while many other PCB designs utilize a 1/2-ounce copper power trace, the power trace 442 of the PCB 250 can be a 1-ounce copper trace. Stated another way, the width (measured in the X and/or Y directions in FIG. 4) and/or the height (measured in the direction extending generally into and/or out of the drawings page) of the power trace 442 can be larger than power traces used in other PCB designs.

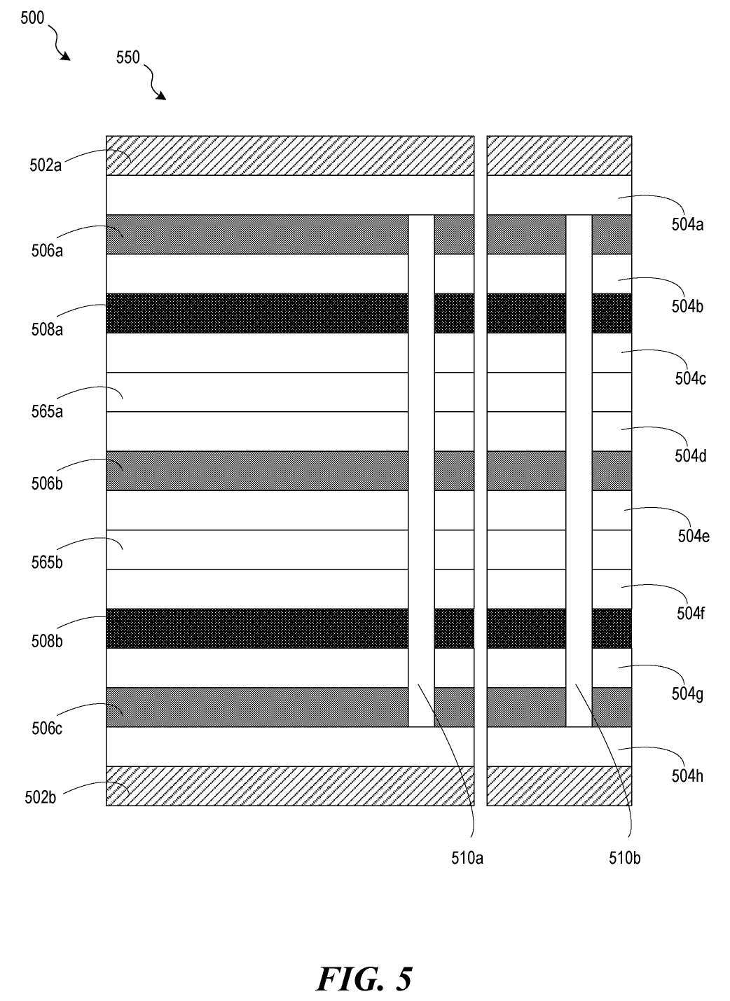

FIG. 5 illustrates a partially schematic cross-sectional side view of a layer arrangement 500 for a printed circuit board 550 (PCB 550) configured in accordance with various embodiments of the present technology. The PCB 550 can be an example of the PCB 250 of FIGS. 2A-4 or of other PCBs configured in accordance with various embodiments of the present technology. As shown in the layer arrangement 500 of FIG. 5, the PCB 550 includes a surface layer 502a and a surface layer 502b positioned at the top and bottom of the layer arrangement 500, respectively. Between these surface layers 502a and 502b, the layer arrangement 500 includes a plurality of conductor layers 506 (identified individually in FIG. 5 as conductor layers 506a-506c), a plurality of ground plane layers 508(identified individually in FIG. 5 as ground plane layers 508a and 508b), and vias 510a and 510b (e.g., plated through-holes) that extend vertically across multiple ones of the layers 506 and 508 and that can be used to electrically couple two or more of the layers 502, 506, and/or 508 to one another. In some embodiments, the conductor layer 506b can be similar to the conductor layer 406 of FIG. 4 described above. Thus, for example, the conductor layer 506b can include a power trace (not shown) that is similar to the power trace 442 of FIG. 4 (e.g. a power trace or Vin_bulk rail that is configured to couple power input pins (not shown) of the PCB 550 to a PMIC (not shown) mounted on the PCB 550). Additionally, or alternatively, the ground plane layer 508a and/or the ground plane layer 508c can be generally similar to the ground plane layer 308 of FIG. 4 described above.

Similar to the layer arrangement 100 of FIG. 1 described above, the layer arrangement 500 of FIG. 5 includes sections of dielectric material 504 (identified individually in FIG. 5 as sections of dielectric material 504a-504h) interleaved with the surface layers 502a and 502b, the conductor layers 506, and the ground plane layers 508. Each of the sections of dielectric material 504(a) can serve as a filler or spacer between adjacent ones of the layers 502, 506, and 508 of the layer arrangement 500 and (b) can be configured to provide electrical isolation between conductive elements of the immediately adjacent ones of the layers 502, 506, and 508.

Unlike the layer arrangement 100 of FIG. 1, the layer arrangement 500 of FIG. 5 further includes (i) a void 565a positioned between the conductor layer 506b and the ground planes 508a and (ii) a void 565b positioned between the conductor layer 506b and the ground plane 508b. The voids 565a and 565b can be layers of the PCB 550 or portions of the layers that are entirely devoid of conductive elements. For example, the voids 565a and/or 565b can span the entirety of layers of the PCB 550, or the voids 565a and/or 565b can span a significantly larger area than is spanned by a power trace of the conductor layer 506b. As another example, the voids 565a and/or 565b can correspond to conductive elements of the conductor layer 506b. In particular, the voids 565a and/or 565b can generally follow or trace a power trace of the conductor layer 506b such that (a) the voids 565a and/or 565b have a same or generally similar (e.g., slightly larger or slightly smaller) footprint as the power trace of the conductor layer 506b and/or (b) no conductive elements are positioned between the power trace of the conductor layer 506b and the ground planes 508a and 508b.

In some embodiments, the voids 565a and/or 565b can be filled with a non-conductive material (e.g., a dielectric material, such as prepreg or core material). The non-conductive material can be a same dielectric material as used to form one or more of the sections of dielectric material 504c-504f. In other embodiments, the non-conductive material can be a different material from one or more of the sections of dielectric material 504c-504f.

Use of the voids 565a and/or 565b is expected to provide several advantages. For example, because the voids 565a and 565b can be devoid of conductive elements and/or be formed with or filled by non-conductive materials, the voids 565a and 565b are expected to improve the electrical isolation of conductive elements (e.g., a power trace, a Vin_bulk rail) of the conductor layer 506b from the ground plane layers 508a and 508b, respectively, beyond that provided by just the sections of dielectric material 504c-504f alone. In addition, because the voids 565a and 565b occupy the space of the layers immediately adjacent the conductor layer 506b (not counting the sections of dielectric material 504a-504h as "layers" of the PCB 550), the ground plane layers 508a and 508b are pushed out to being two layers away from the conductor layer 506b and are therefore positioned a greater distance (e.g., double the distance) from the conductor layer 506b than the ground plane layers 108a and 108b are positioned from the conductor layer 106b in the layer arrangement 100 of FIG. 1. The increased spacing between the ground plane layers 508a and 508b is expected to further improve the electrical isolation of conductive elements of the conductor layer 506b from the ground planes 508a and 508b. In addition, because the ground plane layers 508a and 508b are pushed out to being two layers away from the conductor layer 506b, two sections of dielectric material 504c and 504d (as opposed to a single or only one section) separate the conductor layer 506b from the ground plane layer 508a and two sections of dielectric material 504e and 504f (as opposed to a single or only one section) separate the conductor layer 506b from the ground plane layer 508b, further improving electrical isolation of the conductor layer 506b from the ground plane layers 508a and 508b. As a result, the insulative properties of the voids 565a and 565b, the increased spacing between the conductor layer 506b and the ground planes 508a and 508b, and/or the use of multiple sections of dielectric material 504 between the conductor layer 506b and the ground planes 508a and 508b are expected to reduce the risk of arc events and/or noise coupling between conductive elements of the conductor layer 506b and the ground plane layers 508a and 508b. As such, the voids 565a and 565b are also referred to herein as "arc reduction voids."

In some embodiments, the PCB 550 may additionally include voids (e.g., thermal relief pads) about the vias 510a and/or 510b. Such voids about the vias 510a and/or 510b can be positioned in same layers of the PCB 550 as the voids 565a and/or 565b. For example, the voids about the vias 510a and/or 510b can be contiguous or integral with the voids 565a and/or 565b. Additionally, or alternatively, such voids about the vias 510a and/or 510b can be positioned in one or more other layers of the PCB 550 than the layers of the PCB 550 in which the voids 565a and/or 565b are located. Similar to the voids 565a and/or 565b, the voids about the vias 510a and/or 510b can be formed with or filled by non-conductive material (e.g., a dielectric material, such as prepreg or core material), and/or can be entirely devoid of conductive elements. Use of voids about the vias 510a and/or 510b is therefore expected to also contribute to reducing the risk of electrical arcing and/or noise coupling to the ground planes 508a and/or 508b. For example, the voids about the vias 510a and/or 510b can act as shields, creating barriers between high-frequency signals and other components and maintaining clean power delivery.

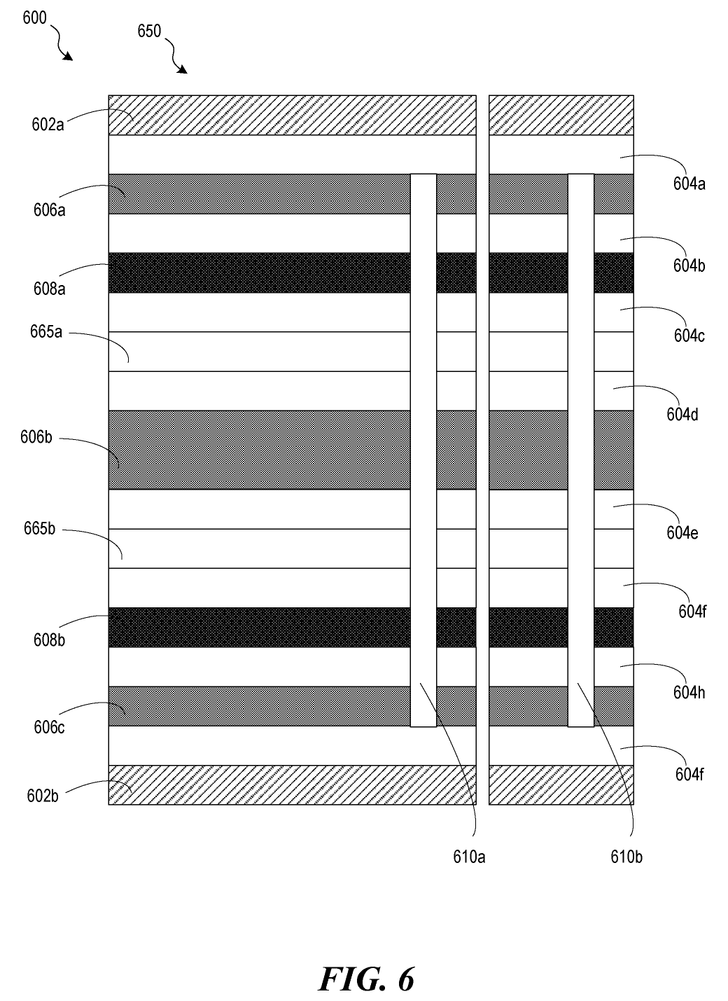

FIG. 6 illustrates a partially schematic cross-sectional side view of another layer arrangement 600 for a printed circuit board 650 (PCB 650) configured in accordance with various embodiments of the present technology. The PCB 650 can be an example of the PCB 250 of FIGS. 2A-4 or of other PCBs configured in accordance with various embodiments of the present technology. As shown, the PCB 650 is generally similar to the PCB 550 of FIG. 5. Therefore, similar references numbers are used across FIGS. 5 and 6 to denote identical or at least generally similar components, and a detail description of these components of the PCB 650 are largely omitted here for the sake of brevity in light of the detailed description provided above with reference to FIG. 5.

Similar to the layer arrangement 500 of FIG. 5, the layer arrangement 600 of FIG. 6 includes voids 665a and 665b positioned in layers of the PCB 650 between (a) a conductor layer 606b and (b) ground planes 608a and 608b, respectively. The voids 665a and 665b can be devoid of all conductive elements and/or can be formed by or filled with non-conductive material (e.g., a dielectric material, such as prepreg or core material). In addition, the conductor layer 606b can be similar to the conductor layer 406 of FIG. 4 described above. Thus, for example, the conductor layer 606b can include a power trace (not shown) that is similar to the power trace 442 of FIG. 4 (e.g. a power trace or Vin_bulk rail that is configured to couple power input pins (not shown) of the PCB 650 to a PMIC (not shown) mounted on the PCB 650), and the voids 665a and/or 665b can generally trace or follow the power trace such that (a) the voids 665a and/or 665b have an identical or at least generally similar (e.g., slightly larger or slightly smaller) footprint as the power trace and/or (b) no conductive elements are positioned between the power trace of the conductor layer 506b and the ground planes 508a and 508b. Alternatively, the void 665a and/or the void 665b can span an entirety of the corresponding layer of the PCB 650, or at least a significantly larger area than is spanned by the power trace in the conductor layer 606b.

In addition, the PCB 650 of FIG. 6 can include vias 610a and/or 610b (e.g., plated through-holes) that extend vertically across multiple ones of the layers 606 and 608 and that can be used to electrically couple two or more of the layers 602, 606, and/or 608 to one another. In some embodiments, the PCB 650 may further include voids (e.g., thermal relief pads) about the vias 610a and/or 610b, which may be positioned in same layers of the PCB 650 as the voids 665a and/or 665b. For example, the voids about the vias 610a and/or 610b can be contiguous or integral with the voids 665a and/or 665b. Additionally, or alternatively, such voids about the vias 610a and/or 610b can be positioned in one or more other layers of the PCB 650 than the layers of the PCB 650 in which the voids 665a and/or 665b are located. The voids about the vias 610a and/or 610b can be formed with or filled by non-conductive material (e.g., a dielectric material, such as prepreg or core material), and/or can be entirely devoid of conductive elements. In some embodiments, the PCB 650 may include additional copper fill underneath the vias 610a and 610b, which is expected to improve the current handling capabilities of the PCB 650. For example, it is expected that the additional copper fill will provide better conductivity between different layers of the PCB 650, potentially reducing bottlenecks in current flow.

In comparison to the PCB 550 of FIG. 5, the PCB 650 of FIG. 6 includes conductive elements with enhanced characteristics. For example, the conductor layer 606b in the layer arrangement 600 is illustrated with a greater thickness than the conductor layer 506b of the layer arrangement 500, which schematically illustrates that conductive elements (e.g., power traces, Vin_bulk rails) of the conductor layer 606b are larger in size (e.g., width and/or thickness) than corresponding conductive elements of the conductor layer 506b of FIG. 5. Use of thicker and/or wider conductive elements in the conductor layer 606b may provide a more robust pathway for power delivery. In some embodiments, use of thicker and/or wider conductive elements in the conductor layer 606b may be made possible by the voids 665a and/or 665b, the increased spacing between the conductor layer 606b and the ground plane layers 608a and/or 608b, and/or use of multiple sections of dielectric material 604 between the conductor layer 606b and each of the ground plane layers 608a and/or 608b. For example, the extra space provided at least in part by the voids 665a and/or 665b may permit use of a larger volume of copper in the conductor layer 606b. As a specific example, increasing the size of a power trace in the conductor layer 606b is expected to reduce the resistance of the power trace, thereby enabling safely increasing current flow through the power trace and/or reducing power losses and heat generation within the PCB 650. In other words, increasing the size of the power trace in the conductive layer 606b is expected to enhance the current-carrying capability of the power trace, which may allow the power trace to handle higher input voltages more effectively and therefore be particularly beneficial for memory modules utilizing PMICs with increased voltage requirements.

### C. Conclusion

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments may perform steps in a different order. Furthermore, the various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology.

Where the context permits, singular or plural terms may also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.”

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

What is claimed is:

1. A printed circuit board (PCB), comprising:
a conductor layer comprising an interconnect,
a ground plane layer, and
a layer including a void positioned between the conductor layer and the ground plane layer such that (a) the layer is devoid of any conductive elements positioned between the interconnect and the ground plane layer and (b) the interconnect is electrically isolated from the ground plane layer.

2. The PCB of claim 1, wherein the void is formed at least in part by or filled at least in part by a non-conductive material.

3. The PCB of claim 2, wherein the non-conductive material includes prepreg or core material.

4. The PCB of claim 1, wherein the void has a footprint that corresponds to a footprint of the interconnect.

5. The PCB of claim 1, wherein the void spans an entirety of the layer of the PCB or an area larger than an area spanned by the interconnect.

6. The PCB of claim 1, further comprising a first section of dielectric material different from the void and positioned between the conductor layer and the layer including the void.

7. The PCB of claim 6, further comprising a second section of dielectric material different from the void and positioned between the layer including the void and the ground plane layer.

8. The PCB of claim 1, wherein the ground plane layer is a first ground plane layer, the layer is a first layer, and the void is a first void, and wherein the PCB further comprises:
a second ground plane layer positioned on a side of the conductor layer opposite the first ground plane layer, and
a second layer including a second void positioned between the conductor layer and the second ground plane layer such that (a) the second layer is devoid of any conductive elements positioned between the interconnect and the second ground plane layer and (b) the interconnect is electrically isolated from the second ground plane layer.

9. The PCB of claim 8, further comprising:
a first section of dielectric material different from the first void and positioned between the conductor layer and the first ground plane layer; and
a second section of dielectric material different from the second void and positioned between the conductor layer and the second ground plane layer.

10. The PCB of claim 9, further comprising:
a third section of dielectric material different from the first void, positioned between the conductor layer and the first ground plane layer, and positioned on a side of the first void opposite the first section of dielectric material; and
a fourth section of dielectric material different from the second void, positioned between the conductor layer and the second ground plane layer, and positioned on a side of the second void opposite the second section of dielectric material.

11. The PCB of claim 1, further comprising:
a via extending through multiple layers of the PCB; and
an additional void positioned about the via.

12. A memory module, comprising:
a printed circuit board (PCB) including—
a conductor layer comprising a power trace;
a ground plane; and
a layer including a void positioned between the conductor layer and the ground plane such that (a) the layer is devoid of any conductive elements positioned between the power trace of the conductor layer and the ground plane and (b) the power trace is electrically isolated from the ground plane;
a voltage input pin configured to receive an input voltage from a host power supply; and
a power management integrated circuit (PMIC) mounted on the PCB, wherein the power trace electrically couples the voltage input pin to the PMIC.

13. The memory module of claim 12, wherein the void is formed at least in part by or filled at least in part by a non-conductive material.

14. The memory module of claim 13, wherein the non-conductive material includes prepreg or core material.

15. The memory module of claim 12, wherein the void has a footprint that is substantially similar to a footprint of the power trace.

16. The memory module of claim 12, wherein the PCB further includes:
a first section of dielectric material different from the void and positioned between the conductor layer and the layer including the void;
a second section of dielectric material different from the void and positioned between the layer including the void and the ground plane; or
a combination thereof.

17. The memory module of claim 12, wherein the PCB further includes:
a via extending through multiple layers of the printed circuit board, wherein the via includes a plated through-hole; and
an additional void positioned around the via, wherein the additional void includes a thermal relief pad.

18. The memory module of claim 12, wherein the power trace is a 1-ounce copper trace or larger.

19. A layer arrangement for a printed circuit board (PCB), the layer arrangement comprising:
a conductor layer comprising a conductive element;
a ground plane layer; and
a void positioned in a layer between the conductor layer and the ground plane layer, wherein the void is configured to contribute toward electrically isolating the conductive element from the ground plane layer, and wherein the void includes a footprint that is at least as large as a footprint of the conductive element.

20. The layer arrangement of claim 19, further comprising one or more sections of dielectric material interleaved with conductor layer, the ground plane layer, and the layer including the void, wherein:
the one or more sections of the dielectric material are different from the void; and
the one or more sections of the dielectric material include—
a first section positioned between the conductive element and the void,
a second section positioned between the void and the ground plane layer, or
a combination thereof.
